(19) United States
(12) Patent Application Publication
(10) Pub. No.: US 2010/0010760 A1
(43) Pub. Date: Jan. 14, 2010

(54) METHOD OF ANALYZING REFLECTION WAVES USING EFFECTIVE IMPEDANCE

(75) Inventors: Jong Ho Kim, Daejeon (KR); Heon Jin Hong, Daejeon (KR); Chang Joo Kim, Daejeon (KR); Il Suek Koh, Kyonggi-Do (KR); Jae Woo Lim, Seoul (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, DAEJEON (KR)

(21) Appl. No.: 12/517,801

(22) PCT Filed: Sep. 19, 2007
(86) PCT No.: PCT/KR07/04535

§ 371 Date: Jun. 4, 2009

(51) Int. Cl. G01R 13/00

(52) U.S. Cl. 702/66

(57) ABSTRACT

Provided is a method for analyzing a reflection wave using effective impedance. The method includes the steps of: a) modeling a reflection surface of a building two-dimensionally; and b) obtaining a reflection wave by radiating a radio wave to the modeled reflection surface and analyzing the obtained reflection wave through making medium uniform.

### TECHNICAL FIELD

The present invention relates to a method for analyzing reflection waves using effective impedance, and more particularly, to a method for analyzing reflection waves using effective impedance that effectively transform electric characteristics such as impedance under assumption that a reflection surface propagating a radio wave is made of single material although the reflection surface is made of complex materials.

### BACKGROUND ART

Recently, there are many researches about a micro cell and a pico cell in actively progress for accommodating more subscribers with limited frequency resources as the demand of mobile communication has abruptly increased.

In order to increase capacity and improve speech quality according to the increment of demand for the wireless communication, wireless communication technology has been gradually advanced to a micro cell or a pico cell based wireless communication technology.

A microcell is a cell having a very small coverage area, for example about a cell with 1 km radius. The microcell has many differences from a typical macrocell. Particularly, the differences between the microcell and the macrocell become further clear in an environment propagating a radio wave. In the macrocell, the environment propagating a radio wave is characterized by the configuration of the land and the distribution of buildings. In the micocell, the environment propagating a radio wave is also characterized by the shape of each building and the arrangement of the buildings as well as the configuration of the land and the distribution of buildings. Since the most of the micro cell technologies were introduced for systems for low speed pedestrians, the microcell needs comparative low transmission power, for example about 100 mw, and a short antenna to cover an area of about 1 km radius. Therefore, the radio wave propagation environment in the microcell is also characterized by the shapes and the arrangement of the buildings, as described above.

Therefore, it is not proper to apply a radio wave propagation model for macrocell to a microcell, and a new radio wave propagation model is required for the radio wave propagation environment for the microcell.

Lately, a ray tracing model, developed based on uniform geometrical theory of diffraction (UTD), has been recognized as the most superior model for describing an environment propagating a radio wave in a microcell. The UTD may be used to predict the propagation path of electromagnetic wave higher than semi microwave band. The UTD use reflection or diffraction characteristics to calculate. However, the ray tracking scheme needs such a long time to perform simulation.

Therefore, there have been many researches in progress for developing a method for estimating a radio wave propagation environment with a flexible and effective calculation process in order to apply it to a base station problem in consideration of the topographical data and propagation loss in a microcell environment.

A time for performing a simulation using the ray-tracing method is decided by a method for finding a propagation path of an electromagnetic wave radiated from a transmitter to a receiver. Such a conventional ray-tracing method may be classified into a ray shooting method and a ray tube method.

The ray shooting method is a method for finding a ray reaching a receiving point by tracing each of rays after a plurality of rays are radiated at a regular interval from a transmission point.

The ray tube method is a method for finding a ray tube reaching a receiving point by tracing each of ray tubs after a plurality of ray tubes at a regular interval from a transmission point. The ray tube means a set of a plurality of rays. It is assumed that all rays in the same ray tube have the same value.

Since the ray shooting method and the ray tube method search all of propagation paths including propagation paths reaching a receiver and propagation paths not reaching the receiver, it takes such a long time to perform a simulation.

In order to overcome such a shortcoming, a method for tracing a propagation path was introduced in Korea Patent No. 10-0205957, issued to SK telecom corp. In the method for tracing propagation path, the propagation path is traced in consideration of the reflecting number and the diffraction number given from a receiver to a transmitter after a tree structure is built for propagation paths between a transmitter and a receiver. The propagation path tracing method reduces the calculation amount by removing unnecessary paths when the ray tracing method is used to calculate paths between a transmitter and a receiver.

However, reflection surfaces are divided into small pieces made of the same material and the divided pieces are analyzed in order to deal with reflection surfaces made of different materials in the above described conventional methods. In this case, the impedance of reflection points need to be calculated whenever a reflection wave is generated and the calculated impedances are reflected in. It is an annoying process.

In other words, if a radio wave is modeled using the ray tracing method, a reflection wave is calculated by expressing the material of a wall surface of a building as impedance. If the wall is made of various materials, the wall must be divided into small pieces each made of the same material in order to form a modeling period with the same material for modeling. Accordingly, the computation amount increases.

In the above-described conventional methods, effective impedance is not total impedance in a horizontal view point of various mediums. The effective impedance denotes impedance by a ratio of voltage and current reflected from the medium in a vertical view point. Therefore, the computation amount thereof and the load of a base station increase.

### DISCLOSURE OF INVENTION

### Technical Problem

Accordingly, the present invention is directed to a method of analyzing reflection waves using effective impedance, which substantially obviates one or more problems due to limitations and disadvantages of the related art.

It is an object of the present invention to provide a method for analyzing a reflection wave using effective impedance, which prevents a computation amount from increasing when a ray tracing method is used with effective impedance under an assumption that a non-uniform reflection surface is made of one material although the reflection surface is made of different materials.

It is another object of the present invention to provide a method for analyzing a reflection wave using effective impedance, which can reduce unnecessary calculation processes and a calculation time by defining and using single impedance that influences to reflection wave generated from the reflection surface when a propagation model of a ray tracing method is used by simply changing a reflection surface made of various materials to single material having the same electric characteristic.

### Technical Solution

According to an aspect of the present invention, there is provided a method for analyzing a reflection wave using effective impedance, including the steps of: a) modeling a reflection surface of a building two-dimensionally; and b) obtaining a reflection wave by radiating a radio wave to the modeled reflection surface and analyzing the obtained reflection wave through making medium uniform.

### ADVANTAGEOUS EFFECTS

Since the radio wave model created using effective impedance according to the present embodiment exactly matches with real radio wave and the reflection wave of non-uniform medium can be replaced with the reflection wave, the computation amount for the radio wave modeling is significantly reduced according to an embodiment of the present invention. Therefore, a radio wave can be easily modeled according to an embodiment of the present invention.

According to an embodiment of the present invention, unnecessary calculation processes and a calculation time can be reduced by uniquely defining impedance that influences to a reflection wave generated from a reflection surface when a radio wave model of a ray tracing method is used through simply changing a reflection surface made of complex materials to a reflection surface made of single material having the same electrical character and using the defined impedance for a single surface. Therefore, the load of a base station can be reduced.

### BRIEF DESCRIPTION OF THE DRAWINGS

The accompanying drawings, which are included to provide a further understanding of the invention, are incorporated in and constitute a part of this application, illustrate embodiments of the invention and together with the description serve to explain the principle of the invention. In the drawings:

FIG. 1 is a diagram illustrating a reflection surface of a building two-dimensionally according to an embodiment of the present invention;

FIG. 2 is a diagram for describing a concept of treating nonuniform reflection surface as a single material reflection surface according to an embodiment of the present invention;

FIG. 3A and FIG. 3B are graphs illustrating a size and a phase of diffusion field of a horizontal polarization according to an embodiment of the present invention; and

FIG. 4A and FIG. 4B are graphs illustrating a size and a phase of diffusion field of a vertical polarization according to an embodiment of the present invention.

### BEST MODE FOR CARRYING OUT THE INVENTION

Reference will now be made in detail to the preferred embodiments of the present invention, examples of which are illustrated in the accompanying drawings.

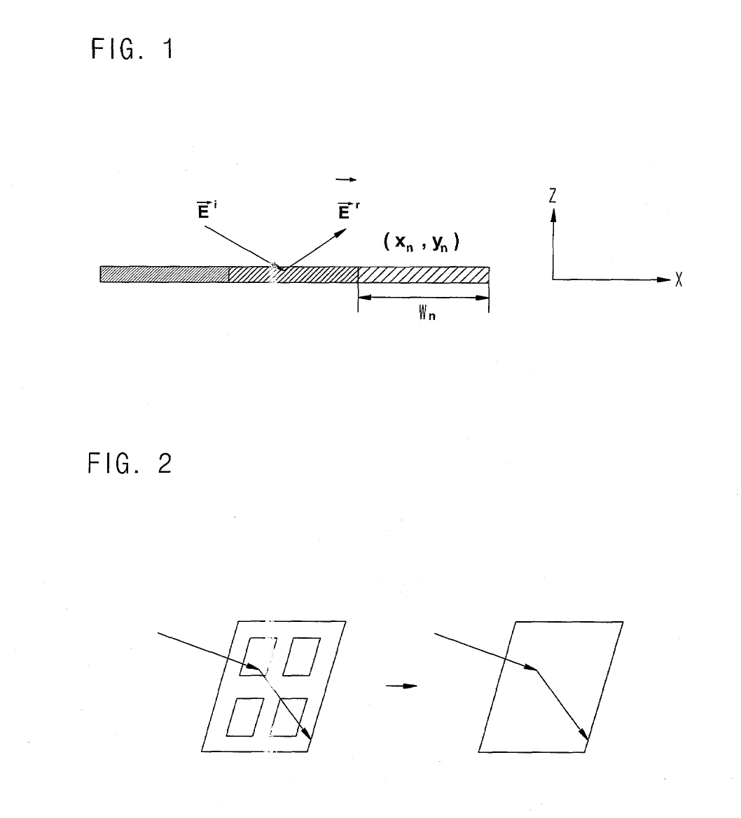

FIG. 1 is a diagram illustrating a reflection surface of a building two-dimensionally according to an embodiment of the present invention.

Referring to FIG. 1, since reflection surfaces of buildings have similar structural characteristics in a vertical direction, the reflection surfaces can be simply modeled two-dimensionally as shown in FIG. 1. Although the reflection surfaces of buildings are modeled as a horizontal surface, the reflection surface of buildings can be modeled as a vertical surface as well as the horizontal surface.

At first, a transmitter 10 outputs an electric field

\vec{E}ⁱ

and a magnetic field

\vec{H}ⁱ

and a receiver 20 receives the electric field

\vec{E}^{r}

and a magnetic field

\vec{H}^{r}

In order to consider the non-uniform medium of building surface, the reflection surface of the non-uniform medium is divided into small pieces, a center point of the n^{th} piece is defined as (Xₙ, Yₙ), and a width of the medium is defined as Wₙ, thereby transforming the reflection surface made of the non-uniform medium to the reflection surface made of uniform medium.

When a horizontal polarization enters, an overall electric field

\vec{E}^{t}

and an overall magnetic field

\vec{H}^{t}

of the uniform medium reflection surface can be expressed as Equation 1 and Equation 2

\vec{E}^{t}=\vec{E}i+\vec{E}^{r}=ĥ(1+Rₕ)e^{ik}^{⁰}^{(k}^{^{x}}^{ₓ}^{+k}^{^{y}}^{ᵢ}^{y)} Equation 1

\vec{H}^{t}=\vec{H}ⁱ+\vec{H}^{r}=−Y₀(\hat{v}₊+Rₕ\hat{v}₋)e^{ik}^{⁰}^{(k}^{^{x}}^{ᵢ}^{x+k}^{^{y}}^{ᵢ}^{y)} Equation 2

In Equation 1 and Equation 2, t denotes an entire field, i denotes an incidence field, and r denotes a reflection field.

k₀

is a frequency in a free space,

Rₕ

is the reflectivity of a horizontal polarization, and

Rᵥ

is the reflectivity of a vertical polarization. If

\hat{k}ᵢ

is set as a propagation vector of a plane wave, it is expressed as

\hat{k}ᵢ=kₓⁱ=\hat{x}+k_{y}ⁱŷ−k_{z}ⁱ\hat{z}

A propagation vector

ĥ

of a vertical direction and a propagation vector

\hat{V}

of a horizontal direction can be expressed as follows.

$$\hat{h} = \frac{1}{{k}_{ρ}^{i}} ( {k}_{y}^{i} \hat{x} - {k}_{x}^{i} \hat{y} ) , {\hat{v}}_{+} = \frac{1}{{k}_{ρ}^{i}} ( {k}_{x}^{i} {k}_{z}^{i} \hat{x} + {k}_{x}^{i} {k}_{z}^{i} \hat{y} + {k}_{ρ}^{i 2} \hat{z} )$$

In the above equation, a propagation vector of a plane wave

\hat{k}ⁱ

can be expressed as

\hat{k}ⁱ=kₓⁱ\hat{x}+k_{y}ⁱŷ=k_{z}ⁱ\hat{z}

Therefore, a propagation vector

\vec{k}^{r}

of a reflective plane wave changes to

\hat{k}^{r}=kₓⁱ\hat{x}+k_{y}ⁱŷ+k_{z}ⁱ\hat{z}

Regardless of

k_{z}ⁱ

,

ĥ

can be expressed as the above equation. However,

\hat{V}

changes to Equation 3.

$${\hat{v}}_{-} = \frac{1}{{k}_{ρ}^{i}} ( - {k}_{x}^{i} {k}_{z}^{i} \hat{x} - {k}_{x}^{i} {k}_{z}^{i} \hat{y} + {k}_{ρ}^{i 2} \hat{z} ) \qquad Equation 3$$

Based on the above equations, the electric current

\vec{J}ₑ

of a received radio wave can be expressed as Equation 4, and the magnetic current

\vec{J}ₘ

of a received radio wave can be expressed as Equation 5.

\vec{J}ₑ=\hat{z}×\vec{H}^{t}=Y₀\vec{e}(1−Rₕ)e^{ik(k}^{^{x}}^{ᵢ}^{x+k}^{^{y}}^{ᵢ}^{y)} Equation 4

\vec{J}ₘ=−\hat{z}×\vec{E}^{t}=−\vec{m}(1+R^{h})e^{ik(k}^{^{x}}^{ᵢ}^{x+k}^{^{y}}^{ᵢ}^{y)} Equation 5

Therefore,

\vec{e}=[k_{y}ⁱk_{z}ⁱ\hat{x}−kₓⁱk_{z}ⁱŷ]/k^{ρ}ⁱ

and

\vec{m}=[kₓⁱ\vec{x}+k_{y}ⁱ\vec{y}]/k_{ρ}ⁱ

, where Y₀ denotes admittance of a radio wave in a free space.

In case of a vertical polarization, the electric current

\vec{J}ₑ

and the magnetic current

\vec{J}ₘ

can be expressed as Equation 6 and Equation 7.

\vec{J}ₑ=Y₀\vec{m}(1+Rᵥ)e^{ik(k}^{^{x}}^{ᵢ}^{x+k}^{^{y}}^{ᵢ}^{y)} Equation 6

\vec{J}ₘ=\vec{e}(1−Rᵥ)e^{ik(k}^{^{x}}^{ᵢ}^{x+k}^{^{y}}^{ᵢ}^{y)} Equation 7

Using Equations 4, 5, 6, and 7, a horizontal diffusion vector and a vertical diffusion vector can be calculated using Equations 8 and 9.

$$\begin{matrix}{\vec{S}}_{h} = - \frac{k}{4} I ( 1 - {R}_{h} ) \hat{r} \times \hat{r} \times \vec{e} & Equation 8 \\ {\vec{S}}_{v} = - \frac{k}{4} I ( 1 + {R}_{v} ) \hat{r} \times \hat{r} \times \vec{m} & Equation 9\end{matrix}$$

Using the Equations, a scattering coefficient can be easily calculated using equation of

$$\vec{E} ∼ \frac{{e}^{i {k}_{0} r}}{r} \vec{S} .$$

If the surface of a building is formed of N pieces, the overall scattering coefficient

\vec{S}^{t}

can be expressed as Equation 10 under an assumption that the overall scattering coefficient is the sum of all of scattering

\vec{S}_{qn}

generated from each piece.

$${\vec{S}}^{t} = {\sum }_{n = 1}^{N} {\vec{S}}_{qn} \qquad Equation 10$$

In Equation 10, q denotes one of a horizontal direction and a vertical direction. Therefore,

\vec{S}_{qn}

is expressed by combining Equations 8 and 9 expressing the scattering vectors of pieces.

FIG. 2 is a diagram for describing a concept of replacing non-uniform reflection surface with single material reflection surface according to an embodiment of the present invention.

Referring to FIG. 2, a non-uniform surface is simply transformed to a uniform surface, and a surface impedance changes to have the same scattering of a propagation direction.

In the propagation direction

kₓⁱ=kₓ^{s}

of a vector,

I=wₙ

Therefore, the scattering vector of the non-uniform surface can be simplified to Equation 11.

$${\vec{S}}_{q} = - \frac{k}{4} {\sum }_{n = 1}^{N} {w}_{n} ( 1 \pm {R}_{q , n} ) \hat{r} \times \hat{r} \times \vec{q} \qquad Equation 11$$

In Equation 11,

\vec{q}

denotes one of an electric vector,

\vec{e}

and a magnetic vector

\vec{m}

A scattering matrix of a uniform surface can be expressed as

$${\vec{S}}_{q} = - \frac{k}{4} w ( 1 \pm {R}_{q , eff} ) \hat{r} \times \hat{r} \times \vec{q} ,$$

and the two scattering vectors must be the same. Equation 12 can be obtained.

$${\sum }_{n = 1}^{N} \frac{{w}_{n}}{w} ( 1 \pm {R}_{q , n} ) = ( 1 \pm {R}_{q , eff} ) \qquad Equation 12$$

Physically, the left side of Equation 12 is the sum of fields reflected from each piece, and the right side of Equation 12 is the sum of fields reflected from one piece.

wₙ/w

denotes a volume fraction. Effective impedance equation, Equation 13, can be obtained by applying the reflection coefficient equation into Equation 12 and simplifying the result.

$${P}_{h , eff} = \frac{{\sum }_{n = 1}^{N} \frac{{w}_{n}}{w} {P}_{h , n} ( 1 + {R}_{h , n} )}{{\sum }_{n = 1}^{N} \frac{{w}_{n}}{w} ( 1 + {R}_{h , n} )} , \\ {P}_{v , eff} = \frac{{\sum }_{n = 1}^{N} \frac{{w}_{n}}{w} ( 1 - {R}_{v , n} )}{{\sum }_{n = 1}^{N} \frac{{w}_{n}}{w} \frac{1}{{P}_{v , n}} ( 1 - {R}_{v , n} )} \qquad Equation 13$$

Since Equation 13 is not a function using frequency as a parameter, Equation 13 can be used in all frequency range. The reflection wave can be analyzed by applying effective impedance equation, Equation 13, to a reflection wave.

It is possible to perform such a calculation in both of a transmitter 10 and a receiver 20. It is preferable that the transmitter 10 performs such a calculation. As described above, the transmitter 10 may be a base station, and the receiver 20 may be another base station or a mobile terminal.

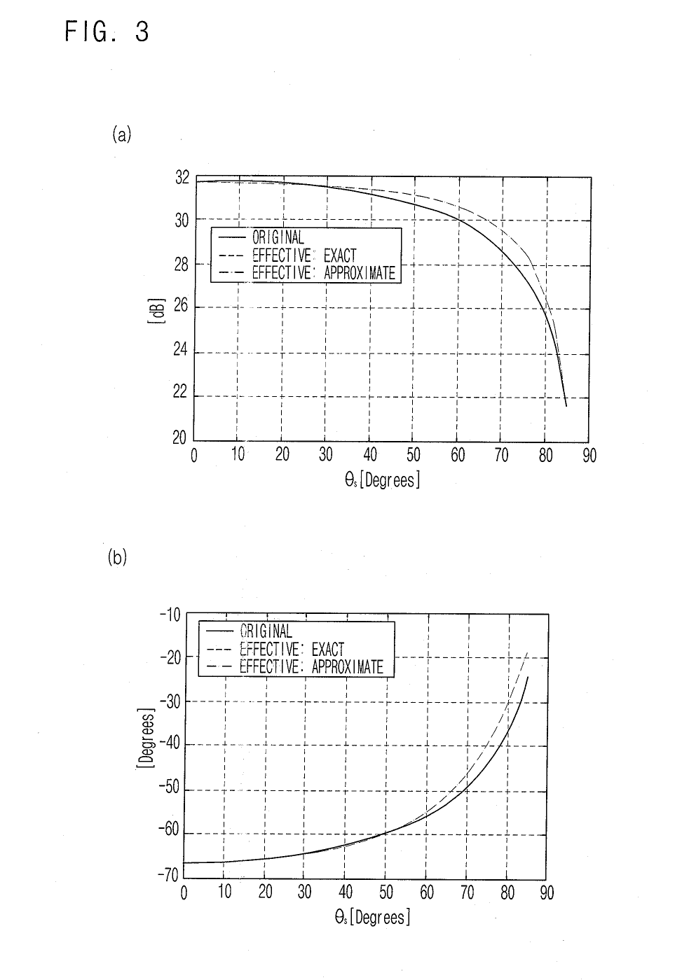

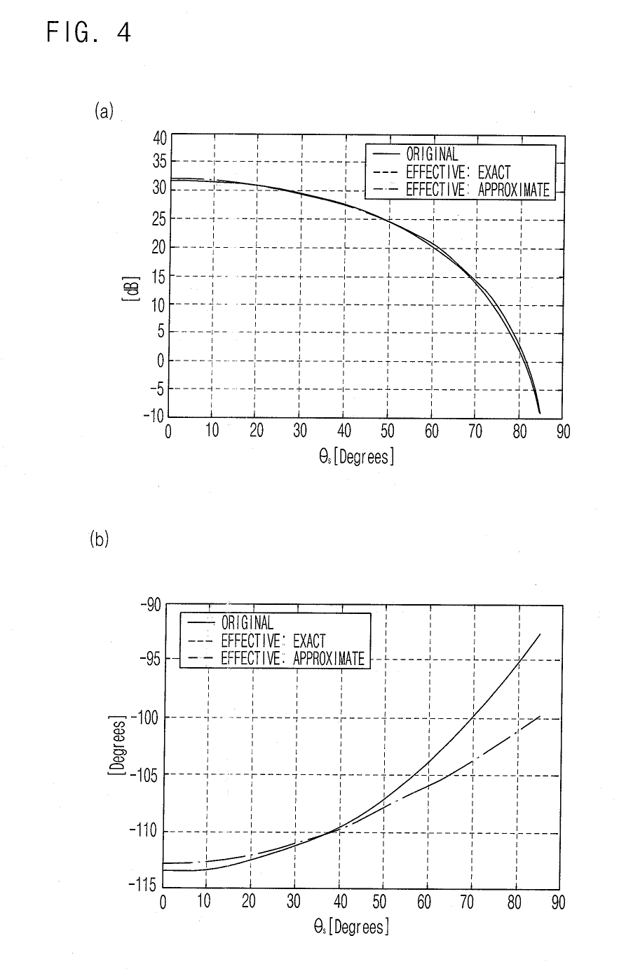

FIG. 3A and FIG. 3B are graphs illustrating a size and a phase of diffusion field of a horizontal polarization according to an embodiment of the present invention, and FIG. 4A and FIG. 4B are graphs illustrating a size and a phase of diffusion field of a vertical polarization according to an embodiment of the present invention.

In FIG. 3A, FIG. 3B, FIG. 4A, and FIG. 4B, a curve ‘original’ denotes physical optics (PO) for a non-uniform surface, and a curve ‘exxact’ is obtained using effective impedance that is a function of incidence angle. A curve ‘approximate’ is obtained using constant impedance. As shown, the curve ‘exact’ is exactly identical to the curve ‘original’ but is slightly different from the curve ‘approximate’. Therefore, the graphs show that the modeling of a radio wave for effective impedance according to the present embodiment exactly matches with real radio wave.

It will be apparent to those skilled in the art that various modifications and variations can be made in the present invention. Thus, it is intended that the present invention covers the modifications and variations of this invention provided they come within the scope of the appended claims and their equivalents.

1. A method for analyzing a reflection wave using effective impedance, comprising the steps of:
a) modeling a reflection surface of a building two-dimensionally; and
b) obtaining a reflection wave by radiating a radio wave to the modeled reflection surface and analyzing the obtained reflection wave through making medium uniform.

2. The method of claim 1, wherein the step a) includes the steps of:
a-1) dividing a uniform medium into a plurality of pieces for considering a nonuniform medium of a building surface; and
a-2) simply changing a non-uniform surface to a uniform surface and changing a surface impedance to have the same scattering in a propagation direction.

3. The method of claim 2, wherein in the step b), an effective impedance equation is obtained, and the reflection wave is analyzed using the obtained effective impedance equation.

4. The method of claim 3, wherein the effective impedance equation is:
$${P}_{h , eff} = \frac{{\sum }_{n = 1}^{N} \frac{{w}_{n}}{w} {P}_{h , n} ( 1 + {R}_{h , n} )}{{\sum }_{n = 1}^{N} \frac{{w}_{n}}{w} ( 1 + {R}_{h , n} )} , \\ {P}_{v , eff} = \frac{{\sum }_{n = 1}^{N} \frac{{w}_{n}}{w} ( 1 - {R}_{v , n} )}{{\sum }_{n = 1}^{N} \frac{{w}_{n}}{w} \frac{1}{{P}_{v , n}} ( 1 - {R}_{v , n} )}$$
where t denotes an entire field, i denotes an incidence field, r denotes a reflection field,
wₙ/w
denotes a volume fraction, R_{h,n} is the reflectivity of n^{th} horizontal polarization, R_{v,n} is the reflectivity of n^{th} vertical polarization, P_{h,n} is the impedance of n^{th} horizontal polarization, and P_{v,n} is the impedance of n^{th} vertical polarization.

5. The method of claim 4, wherein the effective impedance is calculated at a transmitter among the transmitter that transmits the radio wave and a receiver that receives the radio wave.

6. The method of claim 1, wherein in the step b), an effective impedance equation is obtained, and the reflection wave is analyzed using the obtained effective impedance equation.

7. The method of claim 6, wherein the effective impedance equation is:
$${P}_{h , eff} = \frac{{\sum }_{n = 1}^{N} \frac{{w}_{n}}{w} {P}_{h , n} ( 1 + {R}_{h , n} )}{{\sum }_{n = 1}^{N} \frac{{w}_{n}}{w} ( 1 + {R}_{h , n} )} , \\ {P}_{v , eff} = \frac{{\sum }_{n = 1}^{N} \frac{{w}_{n}}{w} ( 1 - {R}_{v , n} )}{{\sum }_{n = 1}^{N} \frac{{w}_{n}}{w} \frac{1}{{P}_{v , n}} ( 1 - {R}_{v , n} )}$$
where t denotes an entire field, i denotes an incidence field, r denotes a reflection field,
wₙ/w
denotes a volume fraction, R_{h,n} is the reflectivity of n^{th} horizontal polarization, R_{v,n} is the reflectivity of n^{th} vertical polarization, P_{h,n} is the impedance of n^{th} horizontal polarization, and P_{v,n} is the impedance of n^{th} vertical polarization.

8. The method of claim 7, wherein the effective impedance is calculated at a transmitter among the transmitter that transmits the radio wave and a receiver that receives the radio wave.
